(19) United States
(12) Patent Application Publication
(10) Pub. No.: US 2016/0018477 A1
(43) Pub. Date: Jan. 21, 2016

(54) MAGNETIC FIELD SENSOR

(71) Applicant: AU Optronics Corporation, Hsin-Chu (TW)

(72) Inventors: Tokuro OZAWA, HSIN-CHU (TW); Chih-Che KUO, HSIN-CHU (TW); Koji AOKI, HSIN-CHU (TW); Mutsumi KIMURA, HSIN-CHU (TW); Takaaki MATSUMOTO, HSIN-CHU (TW); Akito YOSHIKAWA, HSIN-CHU (TW)

(21) Appl. No.: 14/598,369

(22) Filed: Jan. 16, 2015

(30) Foreign Application Priority Data
Jul. 17, 2014 (JP) 2014-147074

(51) Int. Cl. G01R 33/06

(52) U.S. Cl. CPC G01R 33/066

(57) ABSTRACT

A magnetic field sensor using a thin-film field effect transistor configured to control sensitivity appropriately includes a semiconductor film, a drain electrode, a source electrode, a gate electrode, a first hall electrode, and a second hall electrode, in which a drain current passes through a channel region of the semiconductor film between the drain electrode and the source electrode according to a drain voltage applied to the drain electrode and a gate voltage applied to the gate electrode. A hall voltage is generated between the first hall electrode and the second hall electrode according to the drain current and a magnetic field present in the channel region. The gate voltage applied to the gate electrode is substantially higher than a threshold voltage and outside a low voltage range that is substantially lower than the threshold voltage.

### RELATED APPLICATIONS

This application claims priority to Japan Application Serial Number 2014-147074, filed Jul. 17, 2014, which is herein incorporated by reference.

### BACKGROUND

1. Technical Field

The present disclosure relates to a magnetic field sensor using a semiconductor thin film.

2. Description of Related Art

Elements utilizing the Hall Effect (i.e., Hall elements) have been used as magnetic sensors in recent times. If a magnet field is applied to a current passing through such an element, the magnetic sensor generates an electromotive force (Hall voltage) perpendicular to both the direction of the current and the direction of the applied magnetic field. Therefore, the magnetic field can be measured by measuring the Hall voltage.

A magnetic field sensor using a thin-film field effect transistor is known, and may be used in a variety of machines; however, a magnetic field sensor using a thin-film field effect transistor does not exhibit electrical properties that are as stable as those for a field effect transistor using a conventional semiconductor wafer due to the fact that a semiconductor thin film is not a single crystal.

### SUMMARY

The present disclosure provides a magnetic field sensor using a thin-film field effect transistor, in which a sensitivity of the magnetic field sensor may be controlled appropriately.

One aspect of the present disclosure is a magnetic field sensor including a semiconductor thin film, a drain electrode, a source electrode, a gate electrode, a first hall electrode, and a second hall electrode. A drain current passes through a channel region of the semiconductor thin film between the drain electrode and the source electrode according to a drain voltage applied to the drain electrode and a gate voltage applied to the gate electrode. A hall voltage is generated between the first hall electrode and the second hall electrode according to the drain current and a magnetic field present in the channel region. The value of the gate voltage applied to the gate electrode is substantially higher than a threshold voltage and outside a low voltage range that is substantially lower than the threshold voltage.

Another aspect of the present disclosure is a sensor circuit including a magnetic field sensor, an amplifier, a first switch, and a second switch. The magnetic field sensor includes a drain electrode, a source electrode, a gate electrode, a first hall electrode, and a second hall electrode, in which the source electrode of the magnetic field sensor is electrically coupled to a second voltage line. The amplifier includes a first terminal, a second terminal and an output terminal, in which the first terminal of the amplifier is electrically coupled to the first hall electrode, and the second terminal of the amplifier is electrically coupled to the second hall electrode. The first switch includes a first terminal, a second terminal and a control terminal, in which the first terminal of the first switch is electrically coupled to a first voltage line, the second terminal of the first switch is electrically coupled to the drain electrode, and the control terminal of the first switch is electrically coupled to a first gate line. The second switch includes a first terminal, a second terminal and a control terminal, in which the first terminal of the second switch is electrically coupled to a sensing line, the second terminal of the first second is electrically coupled to the output terminal of the amplifier, and the control terminal of the second switch is electrically coupled to a second gate line.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a plan view illustrating a magnetic field sensor according to an embodiment of the present disclosure;

FIG. 2 is a cross-sectional view illustrating the magnetic field sensor taken along line S-S of FIG. 1 according to an embodiment of the present disclosure;

FIG. 3 is a graph illustrating a correlation between gate voltage and Hall voltage according to an embodiment of the present disclosure;

FIG. 4 is another graph illustrating a correlation between gate voltage and Hall voltage according to an embodiment of the present disclosure;

FIG. 5 is a schematic diagram used to describe characteristics of an embodiment of the present disclosure;

FIG. 6 is a schematic diagram used to describe characteristics of an embodiment of the present disclosure;

FIG. 7 is a graph illustrating a correlation between gate voltage and drain current according to an embodiment of the present disclosure;

FIG. 8 is a cross-sectional view of a magnetic field sensor according to another embodiment of the present disclosure;

FIG. 9 is a graph illustrating a correlation between gate voltage and Hall voltage according to another embodiment of the present disclosure;

FIG. 10 is a graph illustrating an enlarged view of an area of FIG. 9;

FIG. 11 is perspective view illustrating a two-dimensional magnetic field meter applying the magnetic field sensor of an embodiment of the present disclosure;

FIG. 12 is a circuit diagram illustrating a part of the structure of the two-dimensional magnetic field meter in FIG. 11 according to an embodiment of the present disclosure; and

FIG. 13 is a layout diagram illustrating a part of the circuit in FIG. 12 according to an embodiment of the present disclosure.

### DETAILED DESCRIPTION

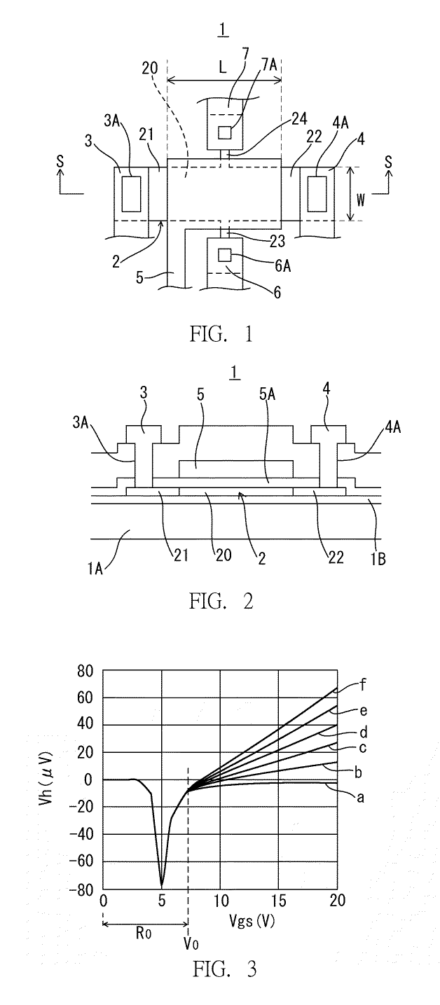

Reference will now be made in detail to embodiments of the present disclosure, examples of which are described herein and illustrated in the accompanying drawings. As shown in FIG. 1 and FIG. 2, in a magnetic field sensor 1 of an embodiment of the present disclosure, a semiconductor thin film 2, a drain electrode 3, a source electrode 4 and a gate electrode 5, which cooperatively form a field effect transistor, are disposed on a substrate 1A (e.g., a resin substrate or a glass substrate) in a state isolated by an insulating film 1B. Moreover, a first hall electrode 6 and a second hall electrode 7 are additionally disposed on the substrate 1A. In the magnetic field sensor 1, a drain current Ids passes through a channel region 20 of the semiconductor film 2 between the drain electrode 3 and the source electrode 4 according to a drain voltage applied to the drain electrode 3 and a gate voltage Vgs applied to the gate electrode 5. In addition, when an external magnetic field is present in the channel region 20, the magnetic field sensor 1 can generate a hall voltage Vh between the first hall electrode 6 and the second hall electrode 7 according to the magnetic field and the drain current Ids. In an embodiment of the present disclosure, the magnetic field sensor 1 includes the structure mentioned above.

Moreover, in the magnetic field sensor 1, the value of the gate voltage Vgs applied to the gate electrode 5 is substantially higher than a threshold voltage V0 and not in a low voltage range R0 substantially lower than the threshold voltage V0 (see FIG. 3 and FIG. 4). Since a threshold voltage (i.e., the threshold voltage V0) is set in the magnetic field sensor 1, the sensitivity thereof can be controlled appropriately. This will be explained in the following embodiments.

It is noted that the semiconductor thin film 2 may be a polycrystalline semiconductor film, an amorphous semiconductor film, or a microcrystalline semiconductor film. The value of the threshold voltage V0 corresponds to the semiconductor type that is used.

A first embodiment in which the semiconductor thin film 2 is a polysilicon film of a polycrystalline semiconductor film will be discussed in the following paragraphs.

Specifically, in the present embodiment, the magnetic sensor 1 is configured to form the structure as described below. That is, as shown in FIG. 1 and FIG. 2, the drain electrode 3 and the source electrode 4 are formed by metal layers, and connected to a drain region 21 and a source region 22 by contact holes 3A and 4A respectively. In the semiconductor thin film 2 at least including the drain region 21, the source region 22 and channel region 20, and the channel region 20 is sandwiched between the drain region 21 and the source region 22. The drain region 21 and the source region 22 are high-concentration n- or p-type impurity regions. The channel region 20 of the semiconductor thin film 2 is an un-doped intrinsic region or a low-concentration n- or p-type impurity region, wherein the low-concentration n- or p-type impurity region is lower than the high-concentration of the drain region 21 and the source region 22. The gate electrode 5 is disposed on the channel region 20 in a state isolated by a gate insulating film 5A means top-gate type. In some embodiments, the gate electrode 5 and the gate insulating film 5A may also be located under the channel region 20 means bottom-gate type. In the first embodiment shown in FIG. 1 and FIG. 2, the gate electrode 5 is disposed on the channel region 20, and therefore, the high-concentration impurity regions of the drain region 21 and the source region 22 are self-aligning by the gate electrode 5.

The first hall electrode 6 and the second hall electrode 7 are disposed on two sides of the channel region 20 of the semiconductor thin film 2 (i.e., two sides in the direction of the width W of the channel region 20). The first hall electrode 6 and the second hall electrode 7 are formed by metal layers, and connected to a first hall region 23 and a second hall region 24 by contact holes 6A and 7A respectively. The first hall region 23 and the second hall region 24 are n- or p-type high-concentration impurity regions, and are formed at protruding parts of the semiconductor thin film 2 on two sides of the same along the direction of the width W of the channel region 20 and in proximity to a center of the channel region 20, wherein the low-concentration n- or p-type impurity region is lower than the high-concentration of the first hall region 23 and the second hall region 24. In the first embodiment shown in FIG. 1 and FIG. 2, the high-concentration impurity regions are self-aligning by the gate electrode 5.

Measurement results with respect to the correlation between a hall voltage Vh (voltage on vertical axis) and a gate voltage Vgs (voltage on horizontal axis) of two experimental samples (sample A and B) of the magnetic field sensor 1 are shown in FIG. 3 and FIG. 4. A doping procedure is not performed in the channel region 20, and therefore, the channel region 20 has a low concentration of impurities, i.e., lower than about 1×10¹⁷ per cubic centimeter (1/cm³). The length L of the channel region of sample A (i.e., the length between the drain region 21 and the source region 22) is about 8,000 micrometers (μm), and the width W is about 1,000 micrometers (μm). The drain voltage applied to the drain electrode 3 is set to be about 5 volts (V). The characteristic curves a, b, c, d, e, and f shown in FIG. 3 are characteristics of sample A respectively corresponding to the presence of magnetic fields of 0 Tesla (T), 0.2 Tesla (T), 0.4 Tesla (T), 0.6 Tesla (T), 0.8 Tesla (T) and 1.0 Tesla (T). The length L of the channel region of sample B is about 4,000 micrometers (μm), and the width W is about 1,000 micrometers (μm). The drain voltage applied to the drain electrode 3 is set to be about 10 volts (V). The characteristic curves g, h, i, j, k and l shown in FIG. 4 are characteristics of sample B respectively corresponding to the presence of magnetic fields of 0 Tesla (T), 0.13 Tesla (T), 0.25 Tesla (T), 0.38 Tesla (T), 0.50 Tesla (T) and 0.61 Tesla (T).

As shown in FIG. 3 and FIG. 4, when the voltage is substantially higher than the threshold voltage V0 (or namely lowest gate voltage Vgs), if the magnetic field increases, the hall voltage Vh increases substantially linearly. In this state, the sensitivity (i.e., the change in the hall voltage Vh corresponding to the change in the magnetic field) is higher if the gate voltage Vgs is higher.

In contrast, in the low voltage range R0 (0 volts to about 7 volts) shown in FIG. 3 and FIG. 4, a hall voltage Vh is generated which is not related to the magnetic field and changes inconsistently. That is to say, as shown in FIG. 3, if the gate voltage Vgs increases from about 4 volts to about 5 volts, the hall voltage Vh decreases rapidly and irrespectively of the magnetic field, and if the gate voltage Vgs increases from about 5 volts to about 7 volts, the hall voltage Vh increases rapidly and irrespectively of the magnetic field. Moreover, as shown in FIG. 4, if the gate voltage Vgs increases from about 4 volts to about 6 volts, the hall voltage Vh increases rapidly and irrespectively of the magnetic field, and if the gate voltage Vgs increases from about 6 volts to about 7 volts, the hall voltage Vh decreases rapidly and irrespectively of the magnetic field.

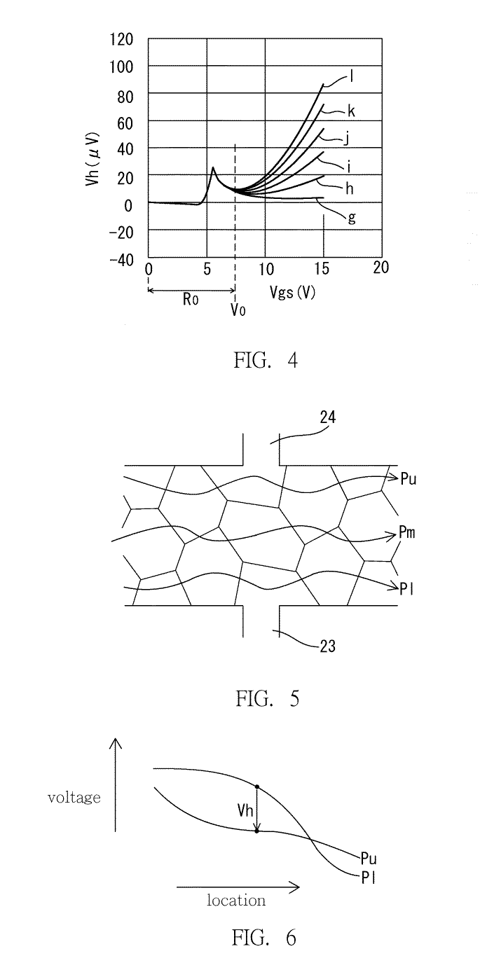

The mechanism by which the hall voltage Vh is unrelated to the magnetic field and changes inconsistently in the low voltage range R0 shown in FIG. 3 and FIG. 4 will be discussed. When the semiconductor thin film 2 is a polycrystalline semiconductor film, a potential barrier exists at a grain boundary. In the low voltage range R0, the potential barrier is higher and the current flows along zig-zag routes Pl, Pm, and Pu shown in FIG. 5. As a result, the symmetry between the first hall region 23 and the second hall region 24 is broken, and a hall voltage Vh with random polarity is generated between the first hall electrode 6 and the second hall electrode 7. For example, as shown in FIG. 6 (where the horizontal axis represents location and the vertical axis represents voltage), the voltage difference between the voltage in proximity to the first hall region 23 generated by the current that flows along zigzag route Pl and the voltage in proximity to the second hall region 24 generated by the current that flows along zigzag route Pu is measured to be the hall voltage Vh. Therefore, the hall voltage Vh in the low voltage range R0 is unrelated to the magnetic field. In addition, due to the fact that the location of the grain boundary differs in each sample, the value and the polarity of the hall voltage Vh of each sample are different. Since such an effect relates to the grain boundary, it is an effect particular to the semiconductor thin film 2 and does not exist in single crystal semiconductors. If the gate voltage Vgs is larger than the low voltage range R0, the potential barrier decreases and the current flow is relatively linear and determined accurately by the magnetic field.

Therefore, in the example of the semiconductor thin film 2 being polysilicon, the voltage shown in the figure at which the hall voltage Vh starts to increase substantially linearly when the magnetic field increases could be set as the threshold voltage V0, and the low voltage range R0 substantially lower than the threshold voltage V0 (i.e., about 0 volts to about 7 volts) is not usable and may be set as a voltage range that cannot be applied. In addition, it may be known that the sensitivity (i.e., the change in the hall voltage Vh corresponding to the change in the magnetic field) can be adjusted and controlled appropriately by applying a gate voltage Vgs that is substantially higher than the threshold voltage V0 to the gate electrode 5 and raising and lowering the value of the gate voltage Vgs.

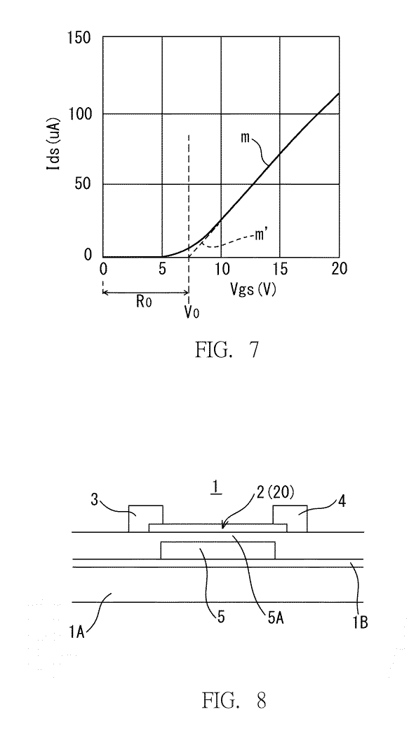

In order to specifically determine the threshold voltage V0, the characteristic curves of the correlation between the hall voltage Vh and the gate voltage Vgs as shown in FIG. 3 and FIG. 4 may be used to choose the proper value. It is also possible to use characteristic curves of the correlation between the drain current Ids and the gate voltage Vgs which will be explained below. Characteristic curve m shown in FIG. 7 is the characteristic curve of the correlation between the drain current Ids (the vertical axis represents current) and the gate voltage Vgs (the horizontal axis represents voltage) of sample A. The drain voltage applied to the drain electrode 3 is set to be about 5 volts. The drain current Ids exhibits a linear correlation (like as a linear function) to the gate voltage Vgs at a higher gate voltage Vgs. Thus, by performing extrapolation at a low voltage area, an extrapolated gate voltage on the extrapolated line m′ for zero drain current Ids (the voltage value of the x-intercept) is obtained, and this may be used to determine the threshold voltage V0. With the characteristic curve m shown in FIG. 7 of the present embodiment, the threshold voltage V0 determined in such a manner is about 7.3 volts.

Next, a second embodiment in which the semiconductor thin film 2 is an amorphous indium gallium zinc oxide (a-IGZO) of the amorphous semiconductor film will be discussed in the following paragraphs. The a-IGZO is an amorphous semiconductor formed using indium (In), gallium (Ga), zinc (Zn) and oxygen (O). In other embodiment, the a-IGZO means oxide semiconductor including other suitable materials such as indium gallium oxide (IGO), indium zinc oxide (IZO), or other suitable.

Specifically, in the present embodiment, the magnetic field sensor 1 is configured to form the structure as described below. As shown in FIG. 8, the drain electrode 3 and the source electrode 4 are formed by metal layers, and connected to the semiconductor thin film 2 (the channel region 20). The semiconductor thin film 2 (the channel region 20) is an n-type low-concentration impurity region. The gate electrode 5 is disposed under the channel region 20 in a state isolated by the gate insulating film 5A. Though omitted in the figure, the first hall electrode 6 and the second hall electrode 7 are disposed at the same location relative to the channel region 20 as shown in FIG. 1.

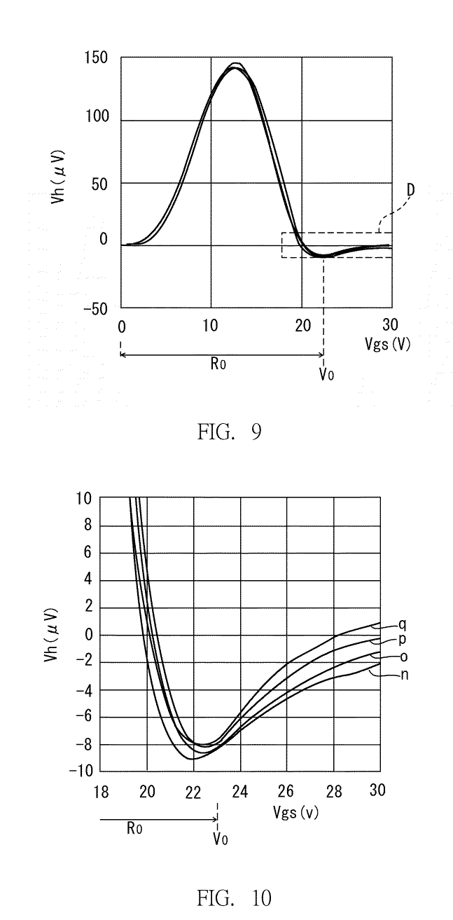

Measurement results with respect to the correlation between a hall voltage Vh (voltage on vertical axis) and a gate voltage Vgs (voltage on horizontal axis) of an experimental sample (sample C) of the magnetic field sensor 1 are shown in FIG. 9. The length L of the channel region 20 of sample C (i.e., the length between the drain electrode 3 and the source electrode 4) is about 4,000 micrometers (μm), and the width W is about 1,000 micrometers (μm). The drain voltage applied to the drain electrode 3 is set to be about 5 volts (V). FIG. 10 is an enlarged diagram illustrating the area D illustrated in FIG. 9. The characteristic curves n, o, p, and q shown in FIG. 10 are characteristics of sample C respectively corresponding to the presence of magnetic fields of 0 Tesla (T), 0.5 Tesla (T), 1.0 Tesla (T) and 1.5 Tesla (T).

As shown in FIG. 10, when the voltage is substantially higher than the threshold voltage V0, if the magnetic field increases, the hall voltage Vh increases substantially linearly. In this state, the sensitivity (i.e., the change in the hall voltage Vh corresponding to the change in the magnetic field) is higher if the gate voltage Vgs is higher.

In contrast, in the low voltage range R0 (0 volts to about 23 volts) shown in FIG. 10 (and FIG. 9), a hall voltage Vh is generated which is not related to the magnetic field and changes inconsistently. That is to say, as shown in FIG. 9, if the gate voltage Vgs increases from about 0 volts to about 13 volts, the hall voltage Vh increases rapidly and irrespectively of the magnetic field, and if the gate voltage Vgs increases from about 13 volts to about 22 volts, the hall voltage Vh decreases rapidly and irrespectively of the magnetic field.

The mechanism by which the hall voltage Vh is unrelated to the magnetic field and changes inconsistently in the low voltage range R0 shown in FIG. 10 (and FIG. 9) will be discussed. When the semiconductor thin film 2 is an amorphous semiconductor film, the semiconductor thin film 2 does not have a grain boundary as a polycrystalline semiconductor does, but due to the amorphous state, the current flows along a percolation route, which is similar to the zigzag routes Pl, Pm and Pu mentioned above. As a result, the symmetry between the first hall electrode 6 and the second hall electrode 7 is broken, and a hall voltage Vh with random polarity is generated. Such an effect does not exist in a single crystal semiconductor, and it is an effect particular to the semiconductor thin film 2. If the gate voltage Vgs is larger than the low voltage range R0, the current flow is relatively linear and determined accurately by the magnetic field.

Therefore, in the example of the semiconductor thin film 2 being a-IGZO, the voltage shown in the figure at which the hall voltage Vh starts to increase substantially linearly when the magnetic field increases could be set as the threshold voltage V0 (or namely lowest gate voltage), and the low voltage range R0 substantially lower than the threshold voltage V0 (i.e., about 0 volts to about 23 volts) is not usable and may be set as a voltage range that cannot be applied. In addition, it may be known that the sensitivity (i.e., the change in the hall voltage Vh corresponding to the change in the magnetic field) can be adjusted and controlled appropriately by applying a gate voltage Vgs that is substantially higher than the threshold voltage V0 to the gate electrode 5 and raising and lowering the value of the gate voltage Vgs. Similar to in the example of semiconductor thin film 2 being the polysilicon, it is also possible to use the characteristic curves of the correlation between the drain current Ids and the gate voltage Vgs to determine the threshold voltage V0.

Consequently, for the magnetic field sensor 1 including the semiconductor thin film 2 of a polycrystalline semiconductor film or an amorphous semiconductor film, the sensitivity can be controlled appropriately by setting the threshold voltage V0 and applying a gate voltage Vgs to the gate electrode 5 that is substantially higher than the threshold voltage V0. When the magnetic field sensor 1 is integrated with circuit elements on the substrate 1A, by setting a suitable threshold voltage V0, regardless of the concentration of impurities for which the channel region 20 is configured to match the characteristics of the circuit elements, the sensitivity can be controlled appropriately. In addition, a microcrystalline semiconductor film usually shares similar properties with a polycrystalline semiconductor film or an amorphous semiconductor film, and so the semiconductor thin film 2 may also be a microcrystalline semiconductor film such as microcrystalline silicon.

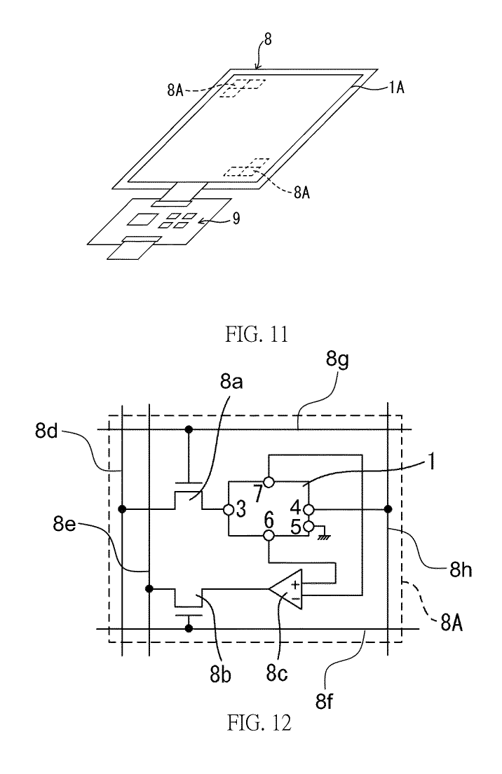

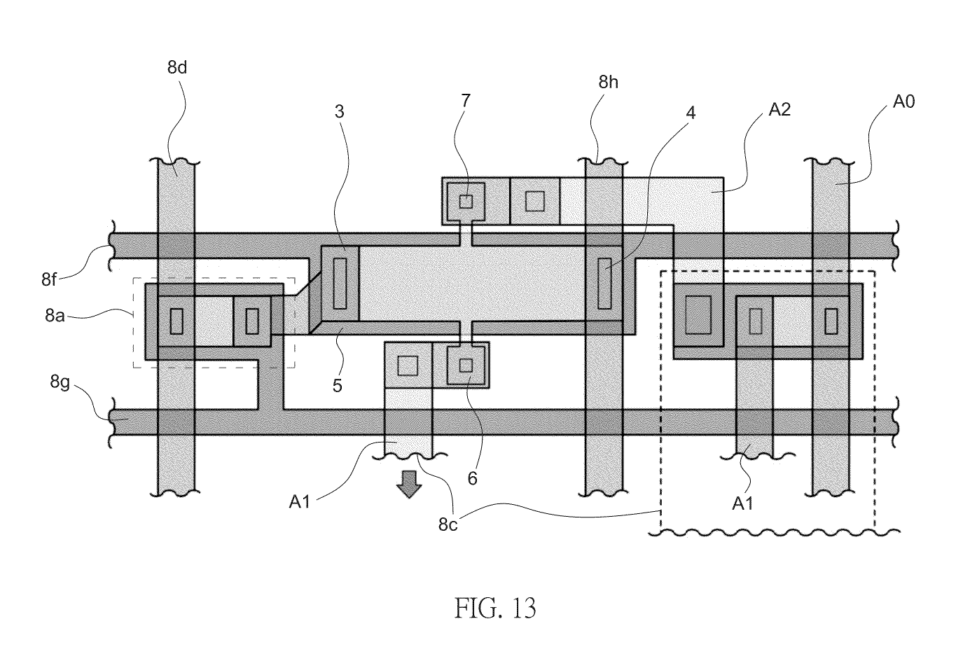

The magnetic field sensor 1 disclosed in the embodiments mentioned above may be used in various types of machines. For example, the magnetic field sensor 1 may be used in a two-dimensional magnetic field meter 8 shown in FIG. 11. A plurality of sensor circuit 8A of the two-dimensional magnetic field meter 8 form a two-dimensional array on the substrate 1A, which may be a resin substrate or a glass substrate of a display device. With additional reference to FIG. 12, each sensor circuit 8A includes not only circuit elements 8a, 8b and 8c, but also a magnetic field sensor 1. At present, the substrate 1A may be made to as large as about 10 square meters (m²) and the substrate may be used to measure the magnetic field of a large area. For example, the two-dimensional magnetic field meter 8 may be controlled by a computer (not shown) through a magnetic field measuring controller 9 which directly controls the two-dimensional magnetic field meter 8. The two-dimensional magnetic field meter 8 may be used in a magnetic field image reader for security purposes, such as for preventing the use of counterfeit coins; a magnetic field measuring device for development of magnetic elements used in motors; a digitized pen-shaped input device (e.g., a stylus); a magnetic anomaly detector configured to detect building structural anomalies, such as an inner broken wire; and other devices.

The sensor circuit 8A including the magnetic field sensor 1, the circuit elements 8c (e.g., an amplifier), the circuit elements 8a (e.g., a first switch), and the circuit elements 8b (e.g., a second switch) is shown in FIG. 12. The magnetic field sensor 1 includes the drain electrode 3, the source electrode 4, the gate electrode 5, the first hall electrode 6, and the second hall electrode 7, in which the source electrode 4 of the magnetic field sensor 1 is electrically coupled to a second voltage line 8h. The amplifier 8c includes a first terminal (or namely first input end), a second terminal (or namely second input end) and an output terminal, in which the first terminal of the amplifier 8c is electrically coupled to the first hall electrode 6, and the second terminal of the amplifier 8c is electrically coupled to the second hall electrode 7. The first switch 8a includes a first terminal (or namely source electrode), a second terminal (or namely drain electrode) and a control terminal (or namely gate electrode), in which the first terminal of the first switch 8a is electrically coupled to a first voltage line 8d, the second terminal of the first switch 8a is electrically coupled to the drain electrode 3 of the magnetic field sensor 1, and the control terminal of the first switch 8a is electrically coupled to a first gate line 8g. The second switch 8b includes a first terminal (or namely source electrode), a second terminal (or namely drain electrode) and a control terminal (or namely gate electrode), in which the first terminal of the second switch 8b is electrically coupled to a sensing line 8e, the second terminal of the second switch 8b is electrically coupled to the output terminal of the amplifier 8c, and the control terminal of the second switch 8b is electrically coupled to a second gate line 8f.

In an embodiment, a magnetic field sensing device may include a matrix array of the aforementioned sensor circuits 8A. For example, the two-dimensional magnetic field meter 8 shown in FIG. 11 may be a magnetic field sensing device, including a matrix array of sensor circuits 8A, and each array element of the matrix array includes the aforementioned sensor circuit 8A respectively.

In each sensor circuit 8A of the matrix array, the drain electrode 3 and the source electrode 4 of the magnetic field sensor 1 are used for supplying necessary voltage. The first hall electrode 6 and the second hall electrode 7 of the magnetic field sensor 1 are used for the output of the hall voltage Vh induced by applying the magnetic field. The supplying voltage is applied to the magnetic field sensor 1 between the first voltage line 8d and the second voltage line 8h via the first switch 8a. When the first switch 8a turns ON according to the applied signal to the first gate line 8g, the magnetic field sensor 1 activates and the output signal of the hall voltage Vh can be output to the amplifier 8c. The amplifier 8c is configured to amplify the hall voltage Vh and output the hall voltage Vh to the sensing line 8e via the second switch 8b. Output signals on the sensing line 8e may be transferred to an external electric board, analog-to-digital converters or other signal detecting units configured to read the output signals. Then, the output signals may be sent to a controller, a micro processing unit (MPU), a personal computer (PC), etc. The output signals on the plural sensing lines 8e may be sent to an external electric board. Then, the output signals may be processed. For example, the output signals may be amplified by amplifiers, digitalized by analog-to-digital converters (ADCs) or rejected noises by data processors on the external electric board.

Reference is made to FIG. 13 in accompany with FIG. 12. FIG. 13 is a layout diagram illustrating a part of the sensor circuit in FIG. 12 according to an embodiment of the present disclosure. A part of the sensor circuit 8A in FIG. 12 is shown in FIG. 13 as a layout example correspondingly, which is manufactured with a-IGZO thin film transistor process. For example, the first terminal (or namely source electrode) of the first switch 8a is connected to the first voltage line 8d, the second terminal (or namely drain electrode) of the first switch 8a is connected to the drain electrode 3 of the magnetic field sensor 1, and the control terminal (or namely drain electrode) of the first switch 8a. The gate electrode 5 of the magnetic field sensor 1 is connected to the second gate line 8f, the source electrode 4 of the magnetic field sensor 1 is connected to the second voltage line 8h, the first hall electrode 6 of the magnetic field sensor 1 is connected to the source electrode (or namely the first terminal) A1 of the amplifier 8c, and the second hall electrode 7 of the magnetic field sensor 1 is connected to the gate electrode (or namely the second terminal) A2 of the amplifier 8c. The drain electrode (or namely the third terminal) A0 of the amplifier 8c is connected to another device. Wherein, the first and second switches 8a, 8b and the amplifier are bottom-gate type of thin film transistor, but the other type TFT can be used, such as top-gate type. It is noted that in FIG. 13, a part of the amplifier 8c, the second switch 8b, and the second gate line 8f are omitted for the sake of brevity.

By adopting the magnetic field sensor 1 and driving condition simultaneously, the a-IGZO layer of the magnetic field sensor 1 can be formed at the same time when the a-IGZO layer of the first switch 8a and the amplifier 8c is formed, as shown in the layout example of FIG. 13. According to the embodiment mentioned above, a magnetic field sensor using a thin-film field effect transistor is provided, in which the sensitivity of the magnetic field sensor may be controlled appropriately.

Although the aspects of the present disclosure and the magnetic field sensor are disclosed in the aforementioned embodiments, the embodiments are not meant to limit the present disclosure. Those skilled in the art should also realize that they may make various changes, substitutions, and alterations herein without departing from the spirit and scope of the present disclosure. For example, in the first embodiment and the second embodiment, the n-type semiconductor may be substituted by a p-type semiconductor and vice versa. In this case, the gate voltage Vgs and drain voltage are negative voltages, and the value of the threshold voltage Vo is also negative and the comparison between different voltages depends on their absolute value. In addition, the location, shape, etc. of the gate electrode 5 may also be changed according to actual needs. In view of the foregoing, it is intended that the present discourse cover modifications and variations of this discourse provided they fall within the scope of the following claims.

What is claimed is:

1. A magnetic field sensor comprising a semiconductor thin film, a drain electrode, a source electrode, a gate electrode, a first hall electrode, and a second hall electrode;
wherein a drain current passes through a channel region of the semiconductor thin film between the drain electrode and the source electrode according to a drain voltage applied to the drain electrode and a gate voltage applied to the gate electrode, and a hall voltage is generated between the first hall electrode and the second hall electrode according to the drain current and a magnetic field present in the channel region;
wherein the gate voltage applied to the gate electrode is substantially higher than a threshold voltage and outside a low voltage range that is substantially lower than the threshold voltage.

2. The magnetic field sensor of claim 1, wherein the semiconductor thin film is a polycrystalline semiconductor.

3. The magnetic field sensor of claim 2, wherein the polycrystalline semiconductor is polysilicon.

4. The magnetic field sensor of claim 1, wherein the semiconductor thin film is an amorphous semiconductor.

5. The magnetic field sensor of claim 4, wherein the amorphous semiconductor is amorphous indium gallium zinc oxide.

6. The magnetic field sensor of claim 1, wherein the semiconductor thin film is a microcrystalline semiconductor.

7. The magnetic field sensor of claim 6, wherein the microcrystalline semiconductor is microcrystalline silicon.

8. The magnetic field sensor of claim 1, wherein the threshold voltage is configured to be an extrapolated gate voltage for zero drain current from drain current-gate voltage characteristics.

9. A sensor circuit, comprising:
a magnetic field sensor having a drain electrode, a source electrode, a gate electrode, a first hall electrode, and a second hall electrode, wherein the source electrode of the magnetic field sensor is electrically coupled to a second voltage line;
an amplifier having a first terminal, a second terminal and an output terminal, wherein the first terminal of the amplifier is electrically coupled to the first hall electrode, and the second terminal of the amplifier is electrically coupled to the second hall electrode;
a first switch having a first terminal, a second terminal and a control terminal, wherein the first terminal of the first switch is electrically coupled to a first voltage line, the second terminal of the first switch is electrically coupled to the drain electrode, and the control terminal of the first switch is electrically coupled to a first gate line; and
a second switch having a first terminal, a second terminal and a control terminal, wherein the first terminal of the second switch is electrically coupled to a sensing line, the second terminal of the second switch is electrically coupled to the output terminal of the amplifier, and the control terminal of the second switch is electrically coupled to a second gate line.

10. A magnetic field sensing device comprising a matrix array of sensor circuits as claimed in claim 9.
